(19) United States
(12) Patent Application Publication
(10) Pub. No.: US 2009/0002080 A1
(43) Pub. Date: Jan. 1, 2009

(54) FREQUENCY DIVIDER AND PHASE LOCKED LOOP USING THE SAME

(75) Inventor: MYEUNG SU KIM, KYUNGKI-DO (KR)

Correspondence Address: LOWE HAUPTMAN HAM & BERNER, LLP, 1700 DIAGONAL ROAD, SUITE 300, ALEXANDRIA, VA, 22314, US

(73) Assignee: SAMSUNG ELECTRO-MECHANICS CO., LTD., KYUNGKI-DO (KR)

(21) Appl. No.: 11/420,724

(22) Filed: Mar. 4, 2008

(30) Foreign Application Priority Data
May 27, 2005 (KR) 10-2005-0045102

(51) Int. Cl. H03L 7/08; H03B 19/12

(52) U.S. Cl. 331/18; 327/118

(57) ABSTRACT

The invention relates to a frequency divider operated digitally and capable of satisfying the Zigbee standard, and a phase locked loop system using the same. The frequency divider includes a plurality of latches in a ring structure with an output of a latter end latch is connected to an input of a former end latch. The frequency divider also includes an input end connected in common to clock ends of the latches, receiving a signal to be divided, and a plurality of output ends connected to the output ends of the latches, outputting divided signals of different phases. The phase locked loop system of the invention has a dividing means dividing an output frequency by 1/P and 1/P+0.5 using the frequency divider, thereby generating the Zigbee channel frequencies at a 5 MHz spacing.

### BACKGROUND OF THE INVENTION

1. Field of the Invention

The present invention relates to a frequency divider which is operated digitally and capable of satisfying low power requirement and a channel spacing of 5 MHz specified by Zigbee, and a phase locked loop system using the same.

2. Description of the Related Art

The Zigbee standard, ratified by the Institute of Electrical and Electronics Engineers (IEEE) 802.15.4, can transfer data at rates up to 250 Kbit/sec and at ranges up to about 75 m and requires low power consumption. It is applicable to home network, security and physical distribution, which requires low speed transmission for a short distance.

More specifically, Zigbee is characterized by low power, low costs, slow rate, and dual physical layer (PHY). It is employed in the 2.4 GHz band and as well as 868 and 915 MHz bands. It adopts Direct Secure Spread Spectrum (DSSS), transmitting data at 20 to 250 kbps and at ranges of 30 m. It is capable of connecting a maximum of 255 devices to a wireless network and establishing a large-scale wireless sensor net for indoors and outdoors.

The most important specification of the Zigbee standard is low power, and improvements are being made on wireless transceivers to meet such a specification.

Among the components of a wireless transceiver requiring the most power is Phase Locked Loop (PLL). The PLL is a device used at both transmission and reception ends, generating frequency needed for converting frequency of transmission and reception signals. Thus, in order for a wireless transceiver to satisfy the Zigbee standard, decreasing the power consumption of the PLL is an essential condition.

FIG. 1 is a block diagram illustrating a basic configuration of a conventional PLL system based on the Zigbee standard.

Referring to FIG. 1, the PLL system includes: a reference signal oscillator 11 for generating a reference frequency signal; a Phase Frequency Detector (RFD) 12 for comparing phase and frequency of the reference signal outputted from the reference signal oscillator 11 with those of an outputted signal of the PLL system to detect phase and frequency differences; a charge pump 13 for converting the difference values detected by the RFD 12 into a voltage signal; a Loop Filter (LP) 14 for filtering out an error signal from the voltage signal from the charge pump 13, compensating a feedback loop to apply the signal to a Voltage Controlled Oscillator (VCO) 15; the VCO 15 for oscillating a frequency in proportion to a voltage inputted through the LP 14, a ½ divider 16 for dividing the output frequency of the VCO 10 by ½; and a pulse swallow divider 17 for dividing the output signal of the ½ divider 16 by 1/N and 1/N+1 by pulse swallow method to provide the divided signal to the PFD 12.

The output signal of the PLL system is the output frequency from the ½ divider 16. That is, the frequency oscillated by the VCO 15 is divided by ½ and provided to a wireless transceiver.

As shown in FIG. 2, the pulse swallow divider 17 includes a prescaler 21 for dividing the output signal fo of the ½ divider by 1/p or 1/(p+1), a program counter 22 for counting the pulse outputted from the prescaler 21 with a frequency dividing ratio of 1/M, and a swallow counter 23 for selecting 1/p or 1/(p+1) as the frequency dividing ratio of the prescaler 21 according to the counting value of the program counter 22.

The swallow counter 23 is used for regulating the frequency dividing ratio of the prescaler 21. While the swallow counter 23 is operating, the frequency dividing ratio of the prescaler 21 is set as 1/(P+1). And when the swallow counter 23 counts S number of pulses, the frequency dividing ratio of the prescaler 21 is set as 1/P. This constitution allows the pulse swallow divider 17 to divide by 1/[(P+1)×M] for S/M hours, and by 1/(P×M) for (M−S)/M hours, where the total frequency division ratio N is equal to (P×(M−S))+(P+1)×S. Here, the set value M of the program counter 22 and the set value S of the swallow counter 23 satisfy the relationship of S<M.

The foregoing PLL system has merits of high operation frequency and low switching noise while having high fixed consumption, which renders it difficult to satisfy the low-power requirement of Zigbee.

Further, in case of a system using 2 MHz IF for transmitting and receiving a Zigbee channel having a spacing of 5 MHz, the above described conventional PLL system renders it difficult to satisfy the Zigbee standard channel.

In particular, in the conventional PLL system, a plurality of basic circuits shown in FIG. 3 are connected in cascade to form a frequency divider. That is, the conventional frequency divider is composed of the basic circuits shown in FIG. 3 connected in cascade, in which a frequency signal to be divided is applied to φ, φ̅, an output Q, Q̅ of a former circuit is applied to D, D̅, and the output Q, Q̅ is connected to D, D̅ of a latter circuit.

Using the circuit shown in FIG. 3 to form the ½ frequency divider 16 and the pulse swallow divider 17 requires a predetermined level of bias current, thus increasing the power consumption and requiring an additional buffer circuit at an output end.

Therefore, the conventional PLL system renders it difficult to satisfy the low-power and channel frequency characteristics of Zigbee.

### SUMMARY OF THE INVENTION

The present invention has been made to solve the foregoing problems of the prior art and it is therefore an object of the present invention to provide a frequency divider digitally operated, satisfying the Zigbee standard of low power.

It is another object of the invention to provide a phase locked loop system operated digitally and using a frequency divider capable of operating with low power, thereby satisfying the Zigbee standard requiring a 5 MHz of channel spacing.

According to an aspect of the invention for realizing the object, there is provided a phase locked loop system including: a reference signal oscillator for generating a reference frequency signal; a phase frequency detector for detecting phase and frequency differences between the reference frequency signal from the reference signal oscillator and a feedback signal; a charge pump for converting the phase and frequency differences detected by the phase frequency detector into a predetermined voltage signal; a voltage controlled oscillator for generating a frequency corresponding to the voltage signal outputted from the charge pump; a first divider for dividing the output frequency of the voltage controlled oscillator by ½; and a pulse swallow divider for dividing the output signal from the first divider by 1/P and 1/P+0.5, where P is a natural number equal to or greater than 1, and providing the divided signal as the feedback signal to the phase frequency detector.

In addition, as another means for achieving the object, the present invention provides the frequency divider including: two latches connected in a ring structure in which an output of a former end is connected to an input of a latter end, and an output of a the latter end is connected to an input of the former end; an input end connected in common to clock ends of both of the two latches, for applying the output signal of the VCO as a clock signal of the latches; and an output end for applying an output signal of the latch of the latter end to the pulse swallow divider.

Each of the latches provided in the frequency divider according to the present invention includes: a first transistor pair in a differential structure, having emitters thereof connected to each other; a second transistor pair in a differential structure, having emitters thereof connected to each other and collectors thereof connected to those of the first transistor pair; a third transistor pair having emitters connected to each other, and bases and collectors thereof cross-connected to each other; a fourth transistor pair having emitters connected to each other, bases and collectors thereof cross-connected to each other, collectors thereof connected to those of the third transistor pair; an input end connected to both of bases of the first and second transistor pairs; an output end connected to all of the collectors of the first to fourth transistor pairs; first and second switching transistors for switching on and off in accordance with a clock signal to apply power to the first and second transistor pairs, the first switching transistor provided between the emitter and a power source of the first transistor pair and the second switching transistor provided between the emitter and a ground of the second transistor pair; and third and fourth switching transistors for switching on and off in accordance with the clock signal to apply power to the third and fourth transistor pairs, taking turns with the first and second switching transistors, the third switching transistor provided between the emitter and a power source of the third transistor pair, and the fourth switching transistor provided between the emitter and a ground.

In addition, each of the latches further includes a feedback resistor connecting the input end with the output end.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a block diagram illustrating a conventional Phase Locked Loop (PLL) system;

FIG. 2 is a block diagram illustrating a pulse swallow divider provided in the conventional PLL system;

FIG. 3 is a basic circuit diagram illustrating a frequency dividing circuit used in the conventional PLL system;

FIG. 4 is a block diagram illustrating a PLL system according to the present invention;

FIG. 5 is a block diagram illustrating a prescaler in the PLL system according to the present invention;

FIG. 6 is a block diagram illustrating a second divider for an example of the frequency divider according to the present invention;

FIG. 7 is a block diagram illustrating a dual mode divider according to the present invention;

FIG. 8 is a detailed circuit diagram of a latch of the divider illustrated in FIG. 6;

FIG. 9 is illustrating timing of the operation of the dual mode divider of the PLL system according to the present invention;

FIGS. 10a to FIG. 10c are graphs illustrating the characteristics of the frequency divider according to the present invention; and

FIGS. 11a to FIG. 11d are graphs illustrating simulation results of the dual mode divider in the PLL system according to the present invention.

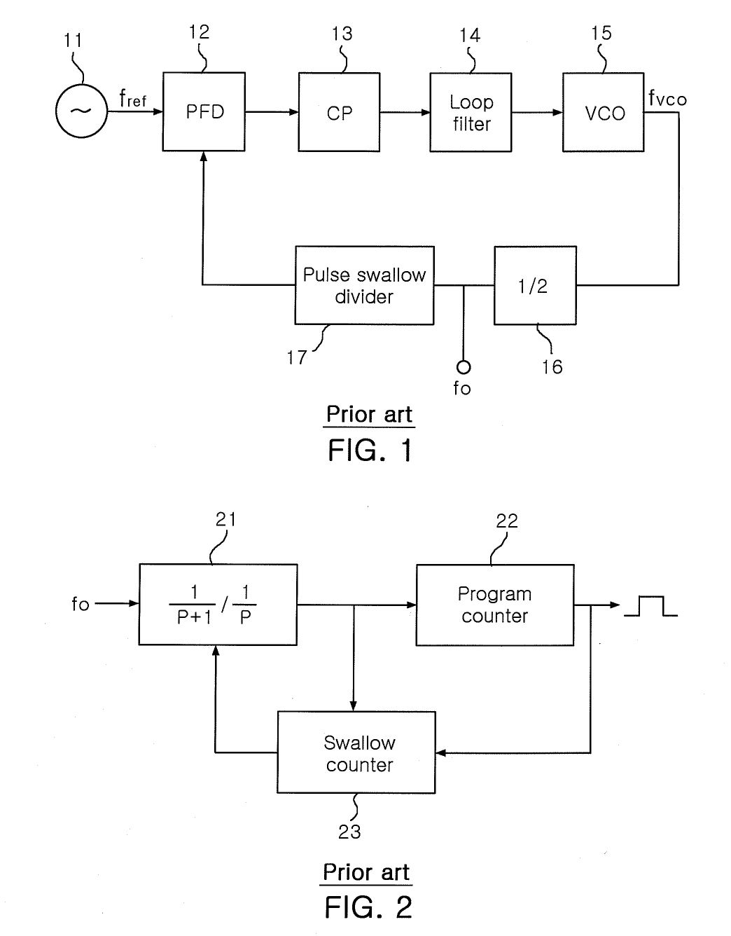

### DETAILED DESCRIPTION OF THE PREFERRED EMBODIMENT

The following description will present a frequency divider and a Phase Locked Loop (PLL) system using the same with reference to the accompanying drawings.

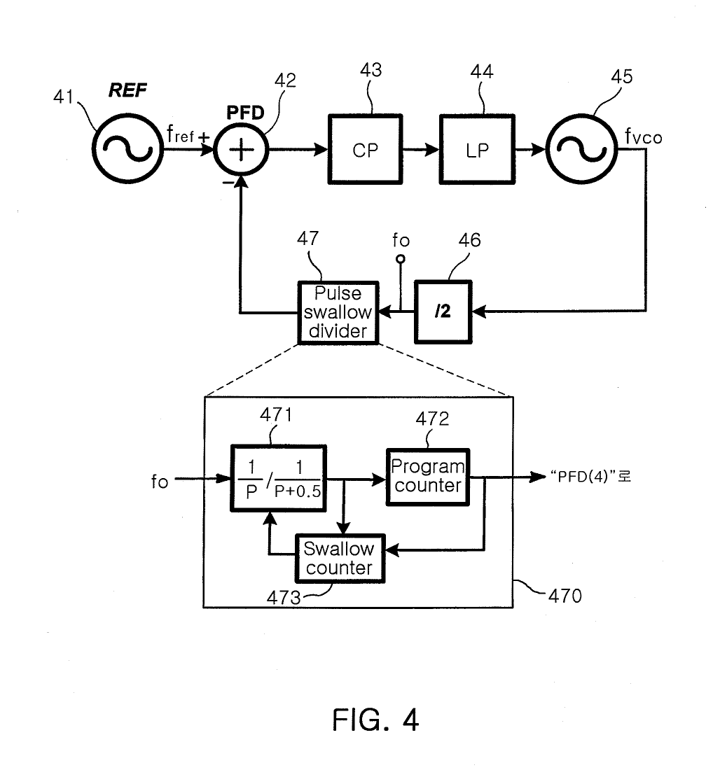

FIG. 4 is a block diagram illustrating the PLL system according to the present invention.

With reference to FIG. 4, the PLL system according to the present invention includes: a reference signal oscillator 41 for generating a reference frequency signal; a Phase Frequency Detector (PFD) 42 for detecting phase and frequency difference between the reference frequency signal from the reference signal oscillator 41 and a feedback signal; a charge pump 43 for converting the phase and frequency differences detected from the PFD into a predetermined voltage value; a Loop Filter (LP) 44 for filtering out an error signal from the voltage signal from the charge pump 43 to compensate a feedback loop; a Voltage Controlled Oscillator (VCO) 45 for generating a frequency corresponding to the voltage signal outputted from the charge pump 43; a first divider 46 for dividing the frequency outputted from the VCO by ½; and a pulse swallow divider 47 for dividing the output frequency from the ½ divider 46 by 1/P and 1/P+0.5 (P is a natural number equal to or greater than 1) according to a selected channel and providing the divided frequency as the feedback signal to the PFD 42.

The pulse swallow divider 47 includes: a prescaler 471 for dividing the output frequency fo from the first frequency divider 46 by 1/P and 1/(P+0.5); a program counter 472 for dividing the signal outputted from the prescaler 471 by 1/M; and a swallow counter 473 for selecting 1/P or 1/(P+0.5) for the dividing ratio of the prescaler 471 according to the counting value S and the selected channel by the program counter 472.

The above described PLL system is capable of generating a plurality of channel frequencies satisfying the Zigbee standard specifying a channel spacing of 5 MHz and IF of 2 MHz by dividing the output frequency by 1/P and 1/(P+0.5).

More specifically, the channel frequencies of the Zigbee standard are set 2405 MHz, 2410 MHz, 2415 MHz, 2420 MHz, for transmission channels and 2403 MHz, 2408 MHz, 2413 MHz, 2423 MHz, . . . for reception channels. The PLL system provided in a low IF receiver receiving the Zigbee channels should be able to generate the above transmission channel frequencies or reception channel frequencies. That is, the PLL system should be capable of generating frequencies at a 5 MHz spacing.

The PLL system according to the present invention can generate the above described Zigbee channel frequencies by setting the dividing ratio values P, M, and S of the pulse swallow divider 47 as shown in following Table 1.

TABLE 1

| | | | | | | Frequency | | |
|---|---|---|---|---|---|---|---|---|
| Channel | | | | | | dividing | | |
| (TX) | Fref(MHz) | P | P + 0.5 | M | S | ratio | Fo(MHz) | Fvco(MHz) |
| 11 | 2 | 8 | 8.5 | 150 | 5 | 1202.5 | 2405 | 4810 |
| 12 | 2 | 8 | 8.5 | 150 | 10 | 1205.0 | 2410 | 4820 |
| 13 | 2 | 8 | 8.5 | 150 | 15 | 1207.5 | 2415 | 4830 |
| . | . | . | . | . | . | . | . | . |
| . | . | . | . | . | . | . | . | . |
| . | . | . | . | . | . | . | . | . |
| | | | | | | Frequency | | |
| Channel | | | | | | dividing | | |
| (RX) | Fref(<Hz) | P | P + 0.5 | M | S | ratio | Fdiv(MHz) | Fvoc(MHz) |
| 11 | 2 | 8 | 8.5 | 150 | 3 | 1201.5 | 2403 | 4806 |
| 12 | 2 | 8 | 8.5 | 150 | 8 | 1204.0 | 2408 | 4816 |
| 13 | 2 | 8 | 8.5 | 150 | 13 | 1206.5 | 2413 | 4826 |
| . | . | . | . | . | . | . | . | . |
| . | . | . | . | . | . | . | . | . |
| . | . | . | . | . | . | . | . | . |

In above Table 1, Fref is a reference signal outputted from the reference signal oscillator 41 and is typically 2 MHz. And Fvco is a frequency value outputted from the VCO 45, and Fo is a final output frequency of the PLL system outputted from the first divider 46.

That is, the prescaler 471 of the pulse swallow divider 47 is set to divide an input signal by ⅛ and 1/8.5, and the program counter 472 is set to divide the signal divided by the prescaler 471 by 1/150. Thus, the pulse swallow divider 47 divides the signal by 1/8.5 for S/150 hours, and divides the signal by ⅛ by 150−S/150, adjusting the final frequency dividing ratio according to the selected channel. For example, in case of channel 11, the total frequency dividing ratio of the pulse swallow divider 47 in this PLL system is (P×M-S)+(P+0.5) S=145+8.5×5=1202.5.

The PLL system according to the present invention divides the output frequency fo by an appropriate frequency dividing ratio for each Zigbee transmission/reception channel set at a 5 MHz spacing. Thereby, all channel frequency signals are compared in phase and frequency with the reference signal of 2 MHZ, thus adjusting the oscillating frequency of the VCO 45. As a result, the PLL system according to the present invention can precisely generate transmission and reception channel frequencies at a 5 MHz spacing required by the Zigbee standard.

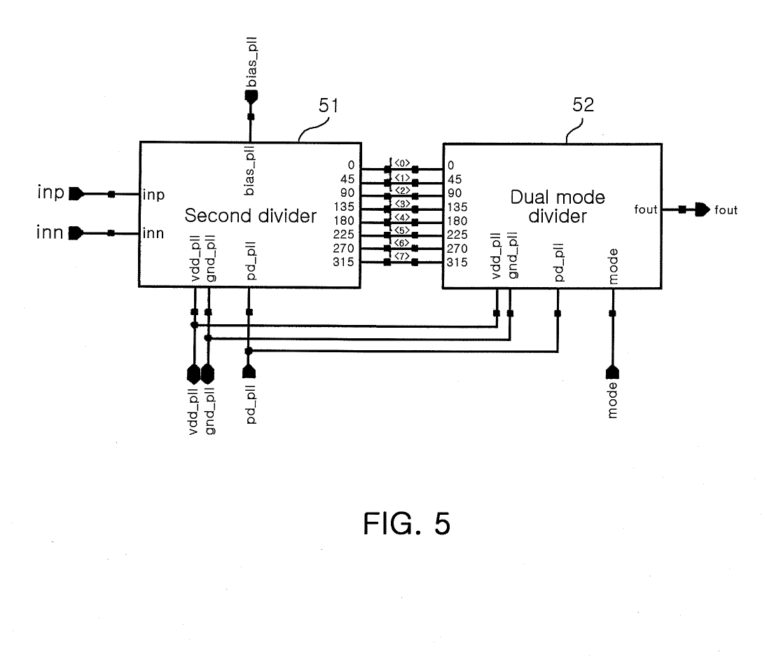

FIG. 5 is a block diagram illustrating a detailed configuration of the prescaler 471 which divides by ⅛ and 1/8.5 in the PLL system according to the present invention.

With reference to FIG. 5, the prescaler 471 includes a second divider 51 for dividing the output frequency of the first divider 46 by ¼, and a dual mode divider 52 for dividing the output signal of the second divider 51 by ½ and 1/2.5 according to the dividing ratio mode applied from the swallow counter 473.

The second divider 51 is a type of ring oscillator with latches connected in cascade, and receives the output frequency of the first divider 46 as a clock signal of the latch, generating ¼ divided signals of 8 phases.

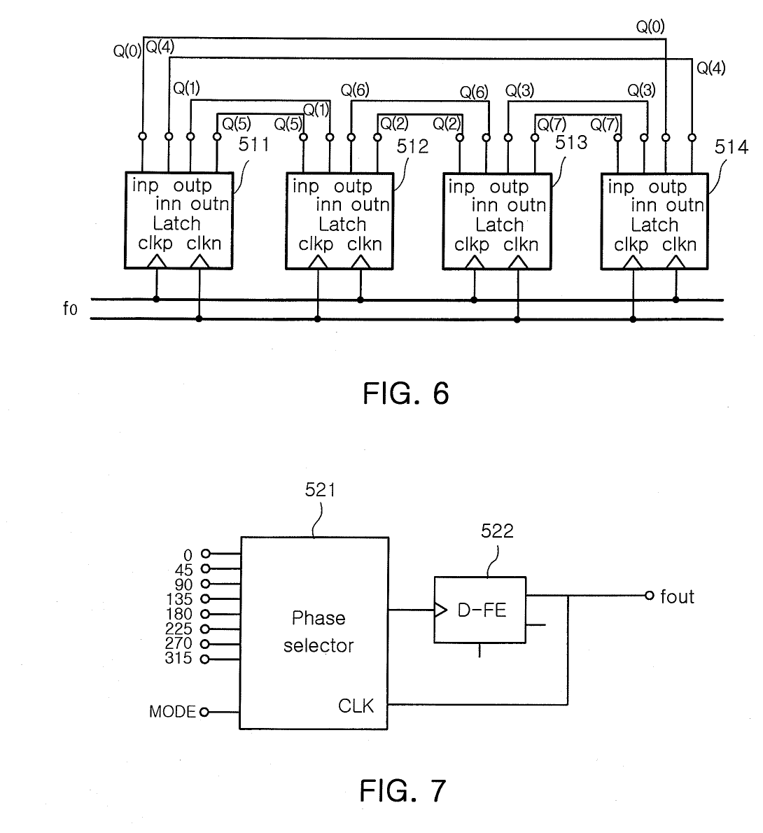

FIG. 6 is a functional block diagram illustrating an example of the second divider 51. With reference to FIG. 6, the second divider 51 according to the present invention is a ring oscillator structure having a plurality of latches 511-514, in which each latch is connected to at an input to an output of a former end latch and at an output to an input of a latter end latch. The latches 511-514 are operated by receiving the signal to be divided as a clock signal.

From the output ends of the plurality of latches 511-514, ¼ divided signals Q(0)-Q(7) of 8 phases are generated with phase differences of 45 degrees.

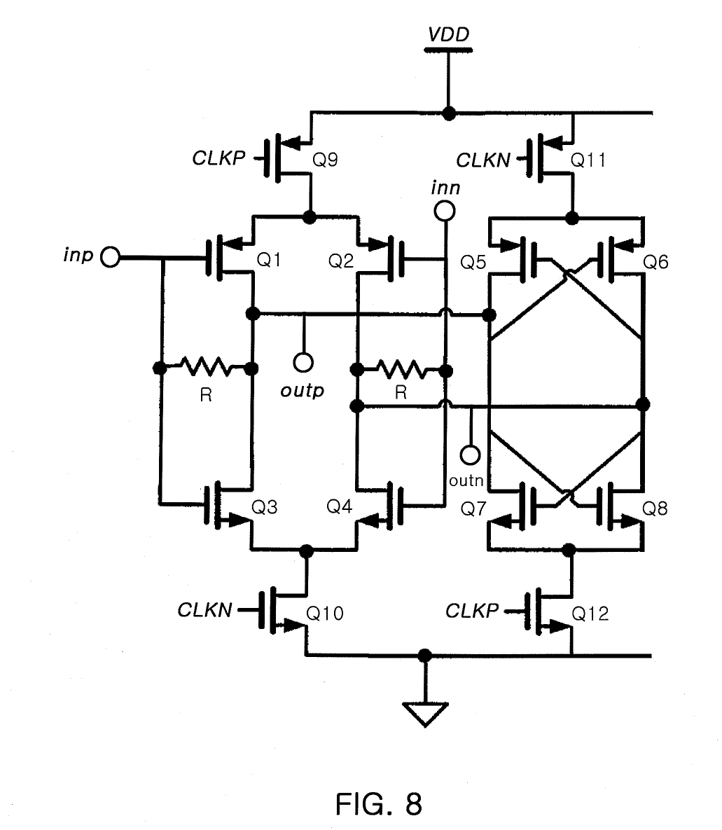

Each of the plurality of latches 511-514 has a configuration as shown in FIG. 8.

With reference to FIG. 8, each of the latches 511-514 of the frequency divider according to the present invention includes: first and second transistor pairs Q1, Q2 and Q3, Q4 having a differential structure, respectively, with bases thereof connected to input ends inp and inn, and collectors thereof connected to output ends outp and outn; third and fourth transistor pairs Q5, Q6 and Q7, Q8 having collectors thereof connected to the output ends outp and outn, bases and collectors thereof cross-connected to each other, and emitters thereof connected to each other; a feedback resistor R connecting the input ends inp and inn with the output ends outp and outn; first and second switching transistors Q9 and Q10 for switching on and off in accordance with clock signals clkp and clkn to apply power to the first and second transistor pairs Q1, Q2 and Q3, Q4, the first switching transistor Q9 provided between a power source and the emitter of the first transistor pair Q1 and Q2 and the second switching transistor Q10 provided between a ground and the emitter of the second transistor pair Q3 and Q4; and third and fourth switching transistors Q11 and Q12 for switching on and off alternately with the first and second switching transistors Q9 and Q10 in accordance with the clock signals clkp and clkn to apply power to the third and fourth transistor pairs Q5, Q6 and Q7, Q8, the third switching transistor Q11 provided between the power source and the emitter of the third transistor pair Q5 and Q6, and the fourth switching transistor Q12 provided between the emitter of the fourth transistor pair Q7 and Q8 and the ground.

With the first and second transistor pairs Q1,Q2 and Q3,Q4 and the third and fourth transistor pairs Q5,Q6 and Q7,Q8 operating alternately at the rising edge of the clock signals clkp and clkn, the latch illustrated in FIG. 8 outputs the information received at the input ends inp and inn at the rising edge to the output ends outp and outn until the next clock signals clkp and clkn are received. Here, the clock signals clkp and clkn are the signals to be divided, i.e., the output signal of the first divider 46.

As described, a plurality of latches 511-514 are connected in a ring structure of a rotational circuit so that the clock signals clkp and clkn are divided while being transmitted to the output ends outp and outn of the latches 511-514.

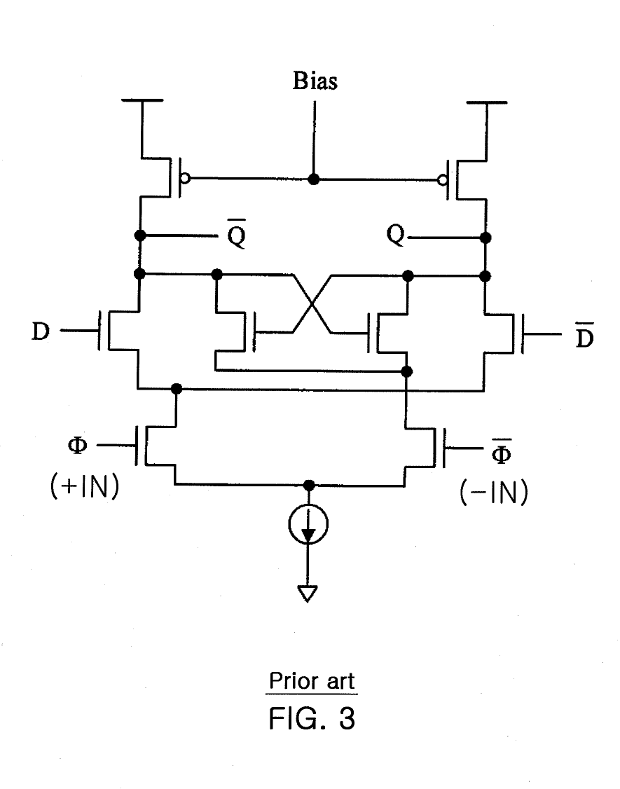

A frequency dividing circuit realized with the above described structure of latch is operated digitally, thus has significantly lower power consumption than the circuit shown in FIG. 3. In addition, the feedback resistor R connects between the input ends inp and inn and the output ends outp and outn, decreasing the level of the clock signals clkp and clkn to 1.0 Vpp. Therefore, even if a low frequency signal of 1.0 Vpp or less is applied, the latch is capable of normally executing frequency dividing operation.

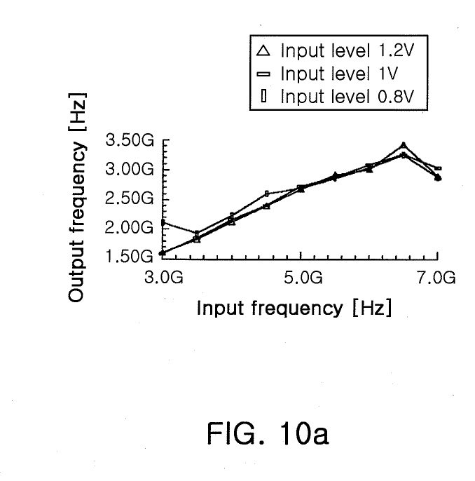

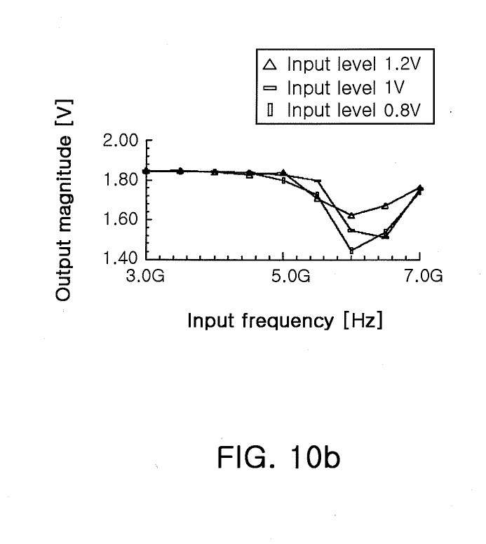

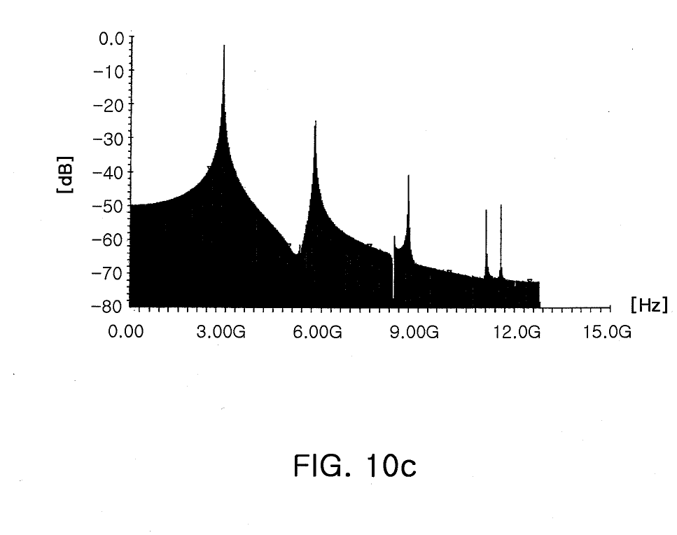

FIG. 10a shows the measurement of the output frequency in comparison with the input frequency of the first divider using the latches according to the present invention. It shows that the output frequency is precisely ½ divided in the range of 3 GHz-6 GHz. Also, the frequency division results were measured when the input frequency was varied to 1.2V, 1V, and 0.8V. As shown in FIG. 10a, the first divider operates normally when the input frequency is about 1.0 Vpp or above.

In addition, FIG. 10b is the measurement of changes in the magnitude of the output frequency of the first divider for each of the varied input frequencies, showing that a stable magnitude of output signal in the range of about 3 GHz to 6 GHz can be obtained.

FIG. 10c is the measurement of self-oscillating frequency at 0 DC bias in the first divider according to the present invention. In general, the ideal self-oscillating frequency is 1.2 to 1.5 times the output frequency, and as shown in FIG. 10c, the graph is close to the ideal condition.

In the frequency dividing circuit using the latch shown in FIG. 8, a frequency dividing ratio is in proportion to the number of latches connected in a ring structure. That is, a ½ dividing circuit requires two latches, and ¼ dividing circuit requires 4 latches 511-514 as shown in FIG. 6.

In the PLL system according to the present invention, the latch in FIG. 8 is used in the first divider 46 and the second divider 51 in the prescaler 471.

The dual mode divider 52 of the prescaler 471 has a configuration as shown in FIG. 7.

With reference to FIG. 7, the dual mode divider 52 includes a phase selector 521 for sequentially selecting and outputting the 8 output signals Q(0)-Q(7) having phase differences of 45 degrees outputted from the second divider 51 according to the mode applied from the swallow counter 473, and a D flip-flop 522 synchronized with the clock signal, outputting the signal outputted from the phase selector 521 to the output end fout. The output signal of the D flip-flop 522 is applied to the phase selector 521 as a clock signal, and the phase selector 521 is synchronized with the output signal to make selection.

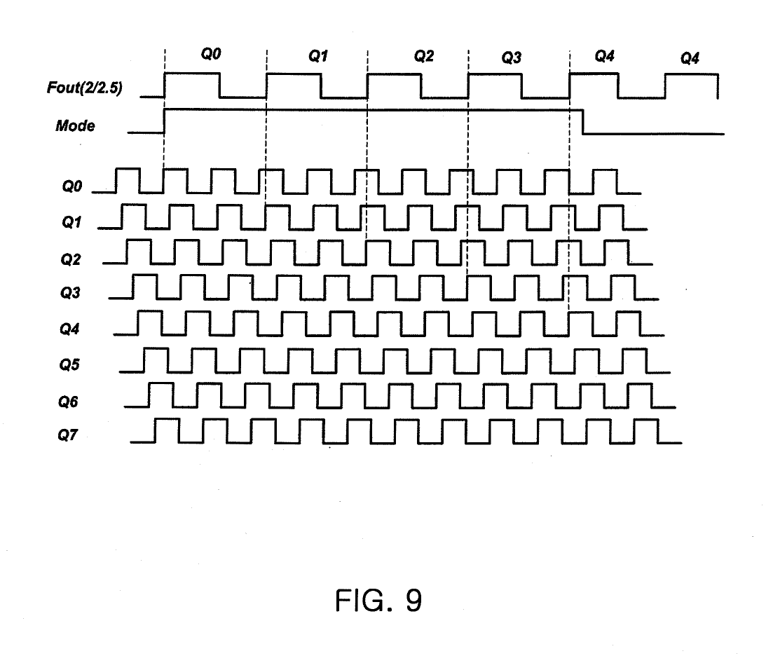

FIG. 9 illustrates operation timing of the dual mode divider 52 shown in FIG. 7.

With reference to FIG. 9, the ¼ divided signal fo/4 of the output signal fo of the first divider 46 is inputted into the phase selector 521 of the dual mode divider 52 as the 8 signals delayed in phases such as 0 degrees, 45 degrees, 90 degrees, 135 degrees, 180 degrees, 225 degrees, 270 degrees, and 315 degrees.

In addition, the mode applied from the swallow counter 473 is inputted into the phase selector 521.

When the mode is logic 0, the phase selector 521 outputs ¼ divided signal fo/4 of the currently selected phase (e.g. j), and when the mode is changed to logic 1, the phase selector 521 sequentially selects and periodically outputs the signal delayed in 45 degrees from the currently selected signal. Then, when the mode is changed back to logic 0, the previously selected signal (i.e., signal delayed in 45 degrees) is continued to be outputted. That is, each time the mode is changed the outputted signal is delayed in a ⅛ phase difference, which is ⅛*4, resulting in a ½ phase difference for the input signal of the prescaler 47. Therefore, while the mode is logic 1, 1/8.5 divided signal is generated.

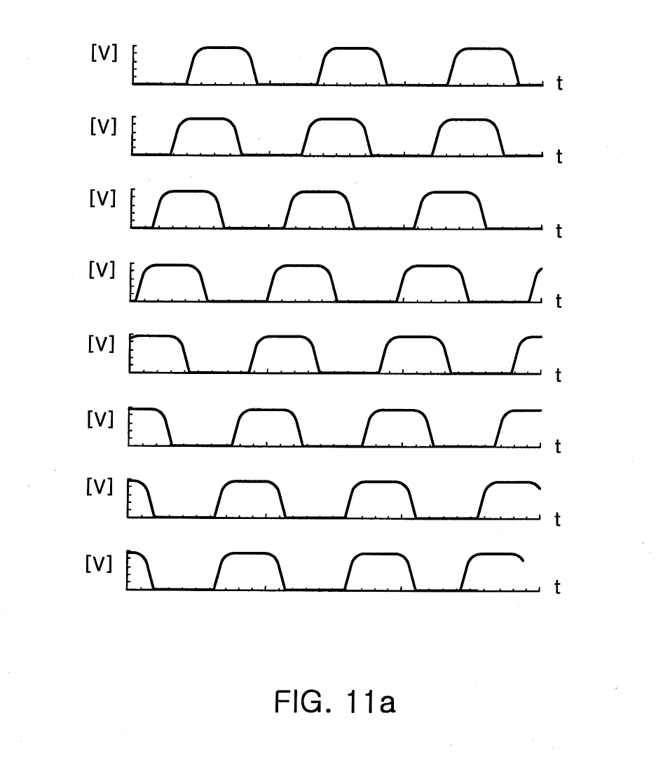

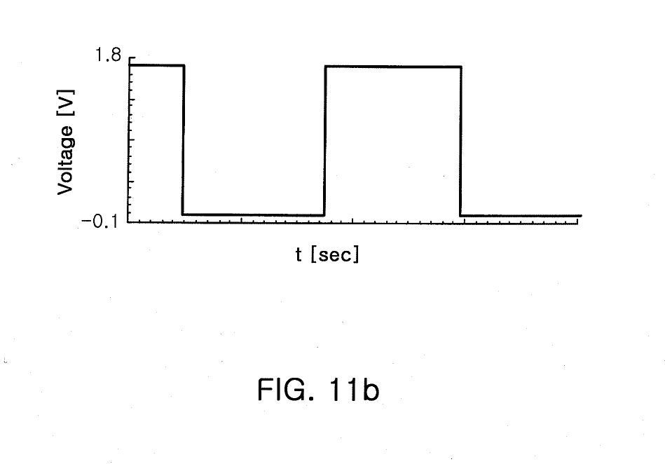

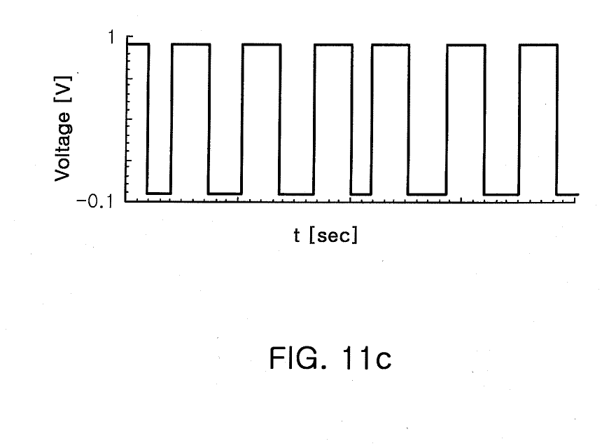

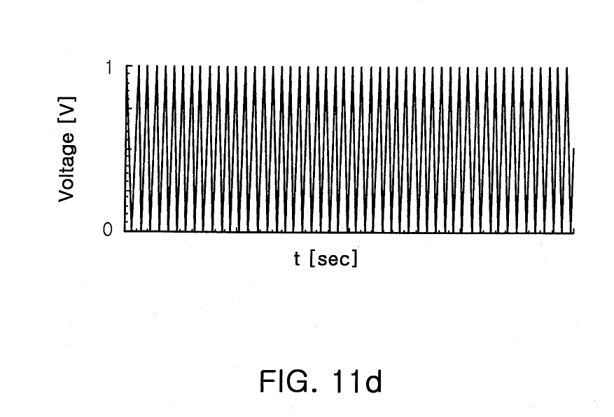

FIG. 11a illustrates signals of 8 phases inputted into the phase selector 521 in the prescaler 47 as described above, and FIG. 11b illustrates the mode outputted from the swallow counter 473, which instructs ⅛ division for logic 0 and 1/8.5 division for logic 1. FIG. 11c illustrates the output signal fout of the dual mode divider 52 with the mode shown in FIG. 11b inputted therein, and FIG. 11d illustrates the input signal received in the prescaler 47.

As set forth above, the present invention provides a digital frequency dividing circuit and a phase locked loop system using the same. The invention significantly reduces the power consumption of the frequency divider and the PLL system from the prior art. Further, a pulse swallow divider dividing in dual mode of N and N+0.5 is provided in the PLL system, thus generating all Zigbee channel frequencies at a channel spacing of 5 MHz and a spacing of 2 MHz between a transmission channel and a reception channel.

While the present invention has been shown and described in connection with the preferred embodiments, it will be apparent to those skilled in the art that modifications and variations can be made without departing from the spirit and scope of the invention as defined by the appended claims.

1. A phase locked loop system comprising:
a reference signal oscillator for generating a reference frequency signal;
a phase frequency detector for detecting phase and frequency differences between the reference frequency signal from the reference signal oscillator and a feedback signal;
a charge pump for converting the phase and frequency differences detected by the phase frequency detector into a predetermined voltage signal;
a voltage controlled oscillator for generating a frequency corresponding to the voltage signal outputted from the charge pump;
a first divider for dividing the output frequency of the voltage controlled oscillator by ½; and
a pulse swallow divider for dividing the output signal from the first divider by 1/P and 1/P+0.5, where P is a natural number equal to or greater than 1, and providing the divided signal as the feedback signal to the phase frequency detector.

2. The phase locked loop system according to claim 1, further comprising a loop filter for filtering out an error signal from the voltage signal outputted from the charge pump to compensate a feedback loop.

3. The phase locked loop system according to claim 1, wherein the first frequency divider comprises:
two latches connected in a ring structure in which an output of a former end is connected to an input of a latter end, and an output of a the latter end is connected to an input of the former end;
an input end connected in common to clock ends of both of the two latches, for applying the output signal of the VCO as a clock signal of the latches; and
an output end for applying an output signal of the latch of the latter end to the pulse swallow divider.

4. The phase locked loop system according to claim 1, wherein the pulse swallow divider comprises:
a prescaler for dividing the output frequency from the first frequency divider by 1/P and 1/(P+0.5);
a program counter for dividing the signal outputted from the prescaler by 1/M to output to the phase frequency detector; and
a swallow counter for operating the prescaler to divide by 1/(P+0.5) for S/M hours and operating the prescaler to divide by 1/p for (M-S)/M hours, according to a frequency value to be generated by the PLL system.

5. The phase locked loop system according to claim 4, wherein the prescaler comprises:
a second divider for dividing the output frequency of the first frequency divider by ¼; and
a dual mode divider for dividing an output frequency of the second frequency divider by ½ or 1/2.5 in accordance with control from the swallow counter.

6. The phase locked loop system according to claim 5, wherein the second frequency divider comprises:
four latches connected in a ring structure in which an output of a former end is connected to an input of a latter end, and an output of the latter end is connected to an input of the former end;
an input end connected in common to clock ends of the four latches, for applying the output signal from the first divider as a clock signal of the four latches; and
a plurality of output ends for outputting an output signal of each of the four latches as ¼ divided signals of 8 phases having phase differences of 45 degrees.

7. The phase locked loop system according to claim 6, wherein the dual mode frequency divider comprises:
a phase selector for selecting a signal having a phase difference of 45 degrees from the current signal, out of the plurality of signals outputted from the plurality of output ends of the second divider in accordance with control from the swallow counter; and
a D flip-flop for receiving the output signal of the phase selector at a D terminal, having an output end connected to a clock end of the phase selector to output an output signal of the phase selector,
whereby the dual mode divider divides an output signal from the second frequency divider by ½ and 1/2.5.

8. The phase locked loop system according to claim 3, wherein each of the latches includes:
a first transistor pair in a differential structure, having emitters thereof connected to each other;
a second transistor pair in a differential structure, having emitters thereof connected to each other and collectors thereof connected to those of the first transistor pair;
a third transistor pair having emitters connected to each other, and bases and collectors thereof cross-connected to each other;
a fourth transistor pair having emitters connected to each other, bases and collectors thereof cross-connected to each other, collectors thereof connected to those of the third transistor pair;
an input end connected to both of bases of the first and second transistor pairs;
an output end connected to all of the collectors of the first to fourth transistor pairs;
a feedback resistor connecting the input end with the output end;
first and second switching transistors for switching on and off in accordance with a clock signal to apply power to the first and second transistor pairs, the first switching transistor provided between the emitter and a power source of the first transistor pair and the second switching transistor provided between the emitter and a ground of the second transistor pair; and
third and fourth switching transistors for switching on and off in accordance with the clock signal to apply power to the third and fourth transistor pairs alternately with the first and second switching transistors, the third switching transistor provided between the emitter and a power source of the third transistor pair, and the fourth switching transistor provided between the emitter and a ground.

9. A frequency divider comprising:
a plurality of latches in a ring structure in which input ends and output ends are connected in a cascade, and an output of a last end latch is connected to an input of a first end latch;
an input end connected in common to clock ends of all latches, inputting a signal to be divided to the latches; and
a plurality of output ends connected to the plurality of output ends of the latches, outputting divided signals having different phases.

10. The frequency divider comprising:
a first transistor pair in a differential structure, having emitters thereof connected to each other;
a second transistor pair in a differential structure, having emitters thereof connected to each other and collectors thereof connected to those of the first transistor pair;
a third transistor pair having emitters connected to each other, and bases and collectors thereof cross-connected to each other;
a fourth transistor pair having emitters connected to each other, bases and collectors thereof cross-connected to each other, collectors thereof connected to those of the third transistor pair;
an input end connected to both of bases of the first and second transistor pairs;
an output end connected to all of the collectors of the first to fourth transistor pairs;
first and second switching transistors for switching on and off in accordance with a clock signal to apply power to the first and second transistor pairs, the first switching transistor provided between the emitter and a power source of the first transistor pair and the second switching transistor provided between the emitter and a ground of the second transistor pair; and
third and fourth switching transistors for switching on and off in accordance with the clock signal to apply power to the third and fourth transistor pairs, taking turns with the first and second switching transistors, the third switching transistor provided between the emitter and a power source of the third transistor pair, and the fourth switching transistor provided between the emitter and a ground.

11. The frequency divider according to claim 10, wherein each of the latches further includes a feedback resistor connecting the input end with the output end.

12. The frequency divider according to claim 9, wherein the number of latches connected in a ring structure is in proportion to a division ratio of the frequency divider.
